(19) United States
(12) Patent Application Publication
(10) Pub. No.: US 2016/0071597 A1
(43) Pub. Date: Mar. 10, 2016

(54) STORAGE DEVICE, MEMORY CONTROLLER AND MEMORY CONTROL METHOD

(71) Applicant: Kabushiki Kaisha Toshiba, Minato-ku (JP)

(72) Inventors: Naoaki KOKUBUN, Yokohama (JP); Osamu Torii, Setagaya (JP); Riki Suzuki, Yokohama (JP)

(73) Assignee: Kabushiki Kaisha Toshiba, Minato-ku (JP)

(21) Appl. No.: 14/624,938

(22) Filed: Feb. 18, 2015

Related U.S. Application Data
(60) Provisional application No. 62/048,028, filed on Sep. 9, 2014.

(51) Int. Cl. G11C 16/10; G06F 11/10; G11C 16/26

(52) U.S. Cl. CPC G11C 16/10; G11C 16/26; G06F 11/1076

(57) ABSTRACT

According to an embodiment, a storage device includes a nonvolatile memory which includes a plurality of memory cells and a memory controller which controls writing on the nonvolatile memory. In a case where an exhaustion degree of the memory cell of the nonvolatile memory is less than a threshold, the memory controller performs a fractional-bit writing in which the number of threshold regions of the memory cell is set to Z (where, Z is a positive value not a power of two). In a case where the exhaustion degree of the memory cell is equal to or higher than the threshold, the memory controller performs an integer-bit writing in which the number of threshold regions of the memory cell is set to 2^{m} (where, 2^{m} is smaller than Z).

### CROSS-REFERENCE TO RELATED APPLICATIONS

This application is based upon and claims the benefit of priority from U.S. Provisional Application No. 62/048,028, filed on Sep. 9, 2014; the entire contents of which are incorporated herein by reference.

### FIELD

Embodiments described herein relate generally to a memory controller, a storage device, and a memory control method.

### BACKGROUND

In a NAND flash memory (hereinafter referred to as a NAND memory), information is stored by means of the amounts of charge retained in the floating gates of memory cells. The threshold voltage is determined according to the amount of charge retained in the floating gate of the memory cell. The threshold voltage refers to a voltage at which the transistor of the memory cell becomes ON (current starts flowing). That is, when a voltage higher than or equal to the threshold voltage is applied to the memory cell, current flows, and when a voltage lower than the threshold voltage is applied, current does not flow. In the NAND memory, a plurality of threshold voltage ranges (areas) are defined with one data value being assigned to each area, and electrons are injected so that the threshold voltage of the memory cell is within the area corresponding to one of the data values. By this means, each memory cell can store a data value.

### BRIEF DESCRIPTION OF THE DRAWINGS

FIG. 1 is a block diagram illustrating an exemplary configuration of a storage device according to a first embodiment;

FIG. 2 is a diagram illustrating an example of a writing method of the first embodiment;

FIG. 3 is a flowchart illustrating an example of a writing sequence of the first embodiment;

FIG. 4 is a diagram illustrating an example of two-stage encoding;

FIG. 5 is a diagram illustrating an example of a writing method of a second embodiment; and

FIG. 6 is a diagram illustrating an example of writing data at the time of overwriting of the second embodiment.

### DETAILED DESCRIPTION

In general, according to an embodiment, there is provided a storage device which includes a nonvolatile memory configured to include a plurality of memory cells, each of which stores data using a plurality of threshold voltage regions, and a memory controller configured to perform reading and writing of data on the nonvolatile memory. The memory cell is configured to set Z threshold regions (where, Z is a positive number not a power of two), and to set 2^{m} threshold regions when m is an integer of 1 or more (where, 2^{m} is smaller than Z). When an exhaustion degree of a first memory cell of the nonvolatile memory is less than a threshold, the memory controller performs a fractional-bit writing in which the number of threshold regions of the first memory cell is set to Z with respect to the first memory cell. When the exhaustion degree of the first memory cell is equal to or higher than the threshold, the memory controller performs an integer-bit writing in which the number of threshold regions of the first memory cell is set to 2^{m} with respect to the first memory cell.

Exemplary embodiments of a storage device, a memory controller and a memory control method will be explained below in detail with reference to the accompanying drawings. The present invention is not limited to the following embodiments.

### First Embodiment

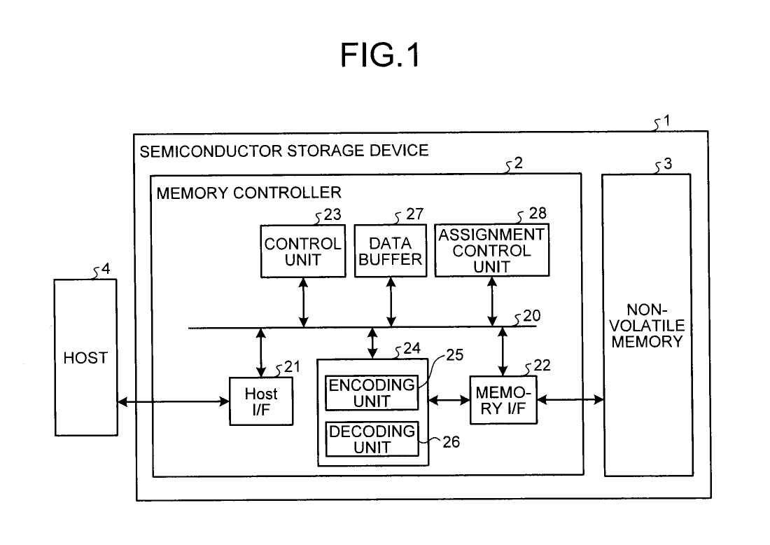

FIG. 1 is a block diagram showing an example configuration of a storage device (semiconductor storage device) according to the first embodiment. The storage device 1 of the present embodiment comprises a memory controller 2 and a nonvolatile memory 3. The storage device 1 is connectable to a host 4. In FIG. 1, a state in which the semiconductor storage device 1 is connected to the host 4 is shown. The host 4 is, for example, an electronic device such as a personal computer or a mobile terminal.

The nonvolatile memory 3 is a semiconductor memory storing data in a nonvolatile manner and, for example, a NAND memory. In the NAND memory, in general, data is written and read out for each of write unit data called page. In the present embodiment, the memory cells of the nonvolatile memory 3 are memory cells of which the number of threshold areas is greater than two.

The memory controller 2 controls writing into the nonvolatile memory 3 according to a write command from the host 4. Further, the memory controller 2 controls reading from the nonvolatile memory 3 according to a read command from the host 4. The memory controller 2 comprises a host I/F 21, a memory I/F 22 (a memory control unit), a control unit 23, an ECC (Error Correcting Code) unit 24, a data buffer 27, and an assignment control unit 28, which are connected to each other via an internal bus 20.

The host I/F 21 outputs commands, user data (write data), and the like received from the host 4 onto the internal bus 20. The host I/F 21 transmits user data read from the nonvolatile memory 3, responses from the control unit 23, and the like to the host 4.

The memory I/F 22 controls writing user data and the like into the nonvolatile memory 3 and reading from the nonvolatile memory 3 based on instructions from the control unit 23.

The control unit 23 controls the storage device 1 across the board. The control unit 23, for example, is a central processing unit (CPU), a micro processing unit (MPU), or the like. When receiving a command from the host 4 via the host I/F 21, the control unit 23 performs control according to the command. For example, the control unit 23, according to a command from the host 4, instructs the memory I/F 22 to write user data and parity into the nonvolatile memory 3. Also, the control unit 23, according to a command from the host 4, instructs the memory I/F 22 to read user data and parity from the nonvolatile memory 3.

The control unit 23 determines a storage area (memory area) on the nonvolatile memory 3 for user data stored in the data buffer 27. User data is stored in the data buffer 27 via the internal bus 20. The control unit 23 performs the determination of the memory area for data in a page unit (page data), which is a write unit. In the present description, the memory cells connected in common to one word line are referred to as a memory cell group. Where the memory cell is a multi-level cell, the memory cell group corresponds to multiple pages. For example, where a multi-level cell capable of two-bit storage (two bits per cell) is used, the memory cell group corresponds to two pages. For example, where a multi-level cell capable of three-bit storage (three bits per cell) is used, the memory cell group corresponds to three pages. In the present description, user data to be written into one page is referred to as unit data. Further, erasing of the nonvolatile memory 3 is performed in a unit called a block. One block includes a plurality of memory cell groups.

The control unit 23 determines the memory region of the nonvolatile memory 3 at a wiring destination for each piece of the unit data. A physical address is assigned to the memory region of the nonvolatile memory 3. The control unit 23 manages the memory region at a writing destination of the unit data using the physical address. The control unit 23 designates the memory region (the physical address) thus determined, and instructs the memory I/F 22 to write the user data to the nonvolatile memory 3. The control unit 23 manages the user data in correspondence with a logical address (a logical address managed by the host 4) and a physical address. When receiving a read command including a logical address from the host 4, the control unit 23 identifies the physical address corresponding to the logical address and instructs the memory I/F 22 to read user data with specifying the physical address.

At the time of writing to the nonvolatile memory 3, the assignment control unit 28 determines an assignment method (hereinafter, referred to as a data value assignment method) of a data value to assign threshold voltage of the memory cell to a plurality of regions. The assignment control unit 28 instructs the memory I/F 22 to perform the writing based on the determined assignment method. Further, at the time of reading from the nonvolatile memory 3, the assignment control unit 28 designates and instructs the data value assignment method to the memory I/F 22. The details of the data value assignment method of the embodiment will be described below.

The ECC unit 24 comprises an encoding unit 25 and a decoding unit 26. The encoding unit 25 encodes first unit data to generate a first code word. Further, the encoding unit 25 encodes second unit data to generate a second code word. In addition, the description herein is made about an example in which the encoding is performed for each piece of the unit data, but the size of the user data subjected to the encoding is not limited to the example. A plurality of code words may be written in one page. In this case, one code word is assumed to be written in the same page or the same memory cell group in the nonvolatile memory 3. The decoding unit 26 performs a decoding using the code word read out of the nonvolatile memory 3. Any scheme may be used for encoding, and, for example, RS (Reed Solomon) code, BCH (Bose Chaudhuri Hocquenghem) code, or LDPC (Low Density Parity Check) code can be used. Further, in the embodiment, the encoding is not essential, and the user data may be written to the nonvolatile memory 3 without performing the encoding. In this case, as described below, in a case where the data value assignment method is discriminated using a result of an error correction process, the encoding is assumed to be performed.

The data buffer 27 temporarily stores user data received from the host 4 until it is stored in the nonvolatile memory 3 and temporarily stores data read from the nonvolatile memory 3 until it is transmitted to the host 4. The data buffer 27 is constituted by, e.g., a general-purpose memory such as an SRAM (Static Random Access Memory) or a DRAM (Dynamic Random Access Memory).

In the NAND memory, the regions of a plurality of threshold voltages are defined, the respective regions are assigned with different data values, and electrons are injected such that the threshold voltage of the memory cell is set in a region corresponding to the data value. By this means, each memory cell can store a data value. In the NAND memory of the related art, the number of regions of distinguishable threshold voltages of the memory cell is a power of two. Hereinafter, the memory cell of which the number of regions of the threshold voltages is a power of two is appropriately referred to as a multi-bit memory cell. In this specification, a case where n-bit data is written in the multi-bit memory cell with data stored using 2ⁿ regions is denoted as MLC2ⁿ. Further, the memory cell on which the writing is performed by MLC2ⁿ is denoted as a memory cell of MLC2ⁿ.

In the NAND memory, when the memory cell is exhausted as time goes by, the threshold voltage may be changed. Therefore, when time goes by, a probability to cause a data reading error is increased. As one of methods of reducing the reading error even after the memory cell is exhausted, a method of reducing the number of regions of the threshold voltages can be considered. In this method, when the number of regions of the threshold voltages is reduced, a width of each region is widened. Thus the reading error of data rarely occurs.

For example, during a period when an exhaustion degree of the memory cell is less than a predetermined threshold (a first value), the writing is performed by MLC8, and when the exhaustion degree of the memory cell becomes the threshold or more, the writing is performed by MLC4. At this time, when a total number of memory cells becomes N_{C}, a storage capacity guaranteed for a user becomes 2N_{C} bits in consideration of exhaustion in the memory cell. Then, even though 2N_{C} bits of the guaranteed storage capacity are sufficient, an actually storing data capacity becomes 3N_{C} bits during a period when the exhaustion degree of the memory cell is low. In this way, the storage capacity is in surplus during a period when the exhaustion degree of the memory cell is low. In the embodiment, the surplus storage capacity generated during a period when the exhaustion degree of the memory cell is low is used in order to increase the storing capacity until the erasing. Specifically, during a period when the exhaustion degree of the memory cell is low (a period when the exhaustion degree of the memory cell is less than the threshold), binary data is written plural times in the memory cell (hereinafter, referred to as a fractional-bit memory cell) in which the number of regions is a non-power of two, so that the storing capacity is increased during a period from the erasing to the next erasing.

In this specification, the writing of the binary data in the fractional-bit memory cell plural times indicates that the binary data is written plural times in a fractional-bit memory cell disclosed in U.S. Provisional Application No. 61/985,323 without the erasing. The disclosures of U.S. Provisional Application No. 61/985,323 are hereby incorporated by reference. In the method disclosed in U.S. Provisional Application No. 61/985,323, writing the binary data q times in the fractional-bit memory cell without the erasing is hereafter denoted by MLCt₁-t₂- . . . -t_{q}. The parameter “t₁” is the number of regions used in a first writing, the parameter “t₂” is the number of regions used in a second writing, . . . , and the parameter “t_{q}” is the number of regions used in a q-th writing. Further, the memory cell written by MLCt₁-t₂- . . . -t_{q} is denoted by the memory cell of MLCt₁-t₂- . . . -t_{q}.

For example, the first writing is assumed to be performed by the data value assignment method using four regions. Further, the second writing is assumed to be performed by the data value assignment method using four regions in which a region unused in the first writing is included without the erasing. The writing in this case is denoted by MLC4-4.

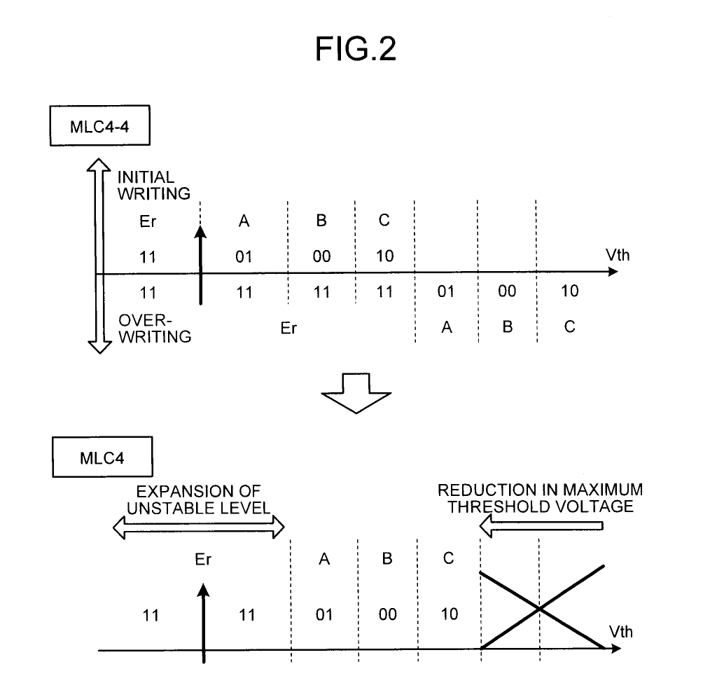

FIG. 2 is a diagram illustrating an example of the writing method of the embodiment. The horizontal axis of FIG. 2 represents a threshold voltage Vth in the memory cell. As illustrated in FIG. 2, during a period when the exhaustion degree of the memory cell is low, the memory controller 2 performs the writing using seven threshold regions by MLC4-4 as illustrated in the upper part of FIG. 2. When the exhaustion degree of the memory cell is equal to or higher than the threshold, the writing is performed by MLC4 as illustrated in the lower part of FIG. 2.

In the writing performed by MLC4-4, two types of writings such as an initial writing and an overwriting are performed. In addition, in this specification, a writing on the memory cell which is not yet written or not written after the erasing is called the initial writing (a first writing), and a writing on the memory cell which is not erased after the initial writing is performed is called the overwriting (a second writing).

As illustrated in the initial writing in the upper part of FIG. 2 and as illustrated by the notations in the upper portion, in the initial writing, a region of a lowest threshold voltage is denoted by region Er (Erase), a region of a second lowest threshold voltage by region A, a region of a third lowest threshold voltage by region B, and a region of a fourth lowest threshold voltage by region C in seven regions. Then, region Er is associated with data value “11”, region A with data value “01”, region B with data value “00”, and region C with data value “10”, respectively. In the initial writing, the memory cells store 2-bit data as described above.

In a case where the overwriting is performed on the memory cell subjected to the initial writing, as illustrated in the overwriting in the upper part of FIG. 2 and as illustrated by the notations in the lower portion, four regions used in a data value assignment (a first data value assignment) of the initial writing is handled as one large region (a combination region). The memory controller 2 performs the overwriting through a data value assignment (a second data value assignment) using the combination region and three regions which have not been used in the data value assignment of the initial writing. Specifically, for example, as illustrated in FIG. 2, the above-mentioned combination region is set to region Er, a region of a fifth lowest threshold voltage to region A, a region of a sixth lowest threshold voltage to region B, and a region of a highest threshold voltage to region C. Then, region Er is associated with data value “11”, region A with data value “01”, region B with data value “00”, and region C with data value “10”, respectively. In the overwriting, the memory cells store 2-bit data as described above. With the above sequence, it is possible to perform the writing two times such as the initial writing and the overwriting without the erasing. In the writing of the binary data in the fractional-bit memory cell plural times, when 2ⁿ+(2^{h}−1) is set to be equal to or lower than Z (where, n and h are integers), the data is written in the initial writing by the first data value assignment in which 2ⁿ data values are associated with 2ⁿ threshold regions. Then, in the overwriting, the data is written by the second data value assignment in which 2^{h} data values are associated with 2^{h} threshold regions.

In a case where the memory cell subjected to the overwriting is further subjected to the writing, the erasing is performed. Then, the memory cell subjected to the erasing is subjected to the above-mentioned initial writing. During a period when the exhaustion degree of the memory cell is low, the initial writing, the overwriting, and the erasing are repeatedly performed as the writing performed by MLC4-4.

Then, when the exhaustion degree of the memory cell becomes equal to or higher than the threshold, the writing is performed by MLC4 as illustrated in the lower part of FIG. 2. In MLC4, 2-bit data is written using the data value assignment (a third data value assignment) in which 2-bit data values are associated with regions of four threshold voltages. In the example of FIG. 2, in seven regions used in MLC4-4, the region of the lowest threshold voltage and the region of the second lowest threshold voltage are set to region Er. Further, the region of the third lowest threshold voltage is set to region A, the region of the fourth lowest threshold voltage is set to region B, and the region of the fifth lowest threshold voltage is set to region C. Then, region Er is associated with data value “11”, region A with data value “01”, region B with data value “00”, and region C with data value “10”, respectively.

In the example of FIG. 2, it is assumed that region Er is unstable, that is, the threshold voltage easily varies, and generally a region of which the maximum value of threshold voltage is low has a high reliability. Therefore, in order to expand region Er and lower the maximum value of the threshold voltage, regions of a high threshold voltage in seven regions used by MLC4-4 are not used.

However, the example of FIG. 2 is illustrated as merely exemplary, and four regions used by MLC4 are not limited to the example of FIG. 2. The region of the lowest threshold voltage may be set to region Er, the region of the second lowest threshold voltage to region A, the region of the third lowest threshold voltage to region B, and the region of the fourth lowest threshold voltage to region C. Alternatively, in a case where the regions other than region Er are unstable, the unstable regions may be expanded without expanding region Er. Further, a plurality of regions may be expanded such as expanding both regions Er and A.

Further, in the above description, the writing by MLC4 corresponds to a writing in which boundary voltages separating the regions in the case of MLC4-4 are not changed and three of the boundary voltages used in MLC4-4 are selected. However, the configuration is not limited to the above description, and MLC4 may be configured not to use the same boundary voltage as that of MLC4-4. For example, a total range (all seven regions in the case of MLC4-4) of the available threshold voltage is divided into four new regions, and the four new regions may be assigned to regions Er, A, B, and C.

In the example of FIG. 2, a writing of 2 bits/cell can be performed in each of the initial writing and the overwriting of MLC4-4, and the writing of 2 bits/cell can be performed even in the writing of MLC4. Therefore, the guaranteed storage capacity is 2N_{C} bits. Herein, as a comparative example, there will be considered an example in which the writing is performed by MLC8 during a period when the exhaustion degree is low, and in a case where the exhaustion degree is equal to or higher than the threshold, the writing is performed by MLC4. In this comparative example, the guaranteed storage capacity is also 2N_{C} bits.

Further, in MLC4-4, a writing of 2 bits/cell can be performed in each of the initial writing and the overwriting. Therefore, in the embodiment, during a period when the exhaustion degree is low, a writing of 4 bits/cell is possible until the erasing. In the embodiment, assuming that a total number of memory cells in the nonvolatile memory 3 is N_{C}, a wiring of 4N_{C} bits is possible until a first erasing. On the other hand, in the above comparative example, during a period when the exhaustion degree is low, that is, in MLC8, a writing of 3N_{C} bits is possible until the first erasing. Therefore, in the embodiment, a writable capacity until the first erasing is larger than that of the comparative example during a period when the exhaustion degree is low.

In FIG. 2, during a period when the exhaustion degree is low, the writing is performed by MLC4-4, and when the exhaustion degree becomes equal to or higher than the threshold, the writing is performed by MLC4, but a specific writing method is not limited to this example. During a period when the exhaustion degree is low, the writing of MLCt₁-t₂- . . . -tₚ is performed using regions of Z (which is a non-power of two) threshold voltages, and when the exhaustion degree becomes equal to or higher than the threshold, the writing is performed by MLC2^{m} (Z may be larger than 2^{m}). For example, during a period when the exhaustion degree is low, the writing may be performed by MLC4-4, and when the exhaustion degree becomes equal to or higher than the threshold, the writing may be performed by MLC2. In this case, the guaranteed storage capacity is N_{C} bits. During a period when the exhaustion degree is low, the writing may be performed by MLC8-4, and when the exhaustion degree becomes equal to or higher than the threshold, the writing may be performed by MLC4. In this case, the guaranteed storage capacity is 2N_{C} bits. Furthermore, during a period when the exhaustion degree is low, the writing may be performed by MLC4-4-4 using ten regions, and when the exhaustion degree becomes equal to or higher than the threshold, the writing may be performed by MLC4. In MLC4-4-4, the initial writing and the overwriting (the first overwriting) are performed using seven regions in an ascending order of the threshold voltage from the lowest one in the ten regions similarly to MLC4-4. Then, the seven regions used until the first overwriting without the erasing are set to one combination region, and the second overwriting is performed using the combination region and the unused three regions.

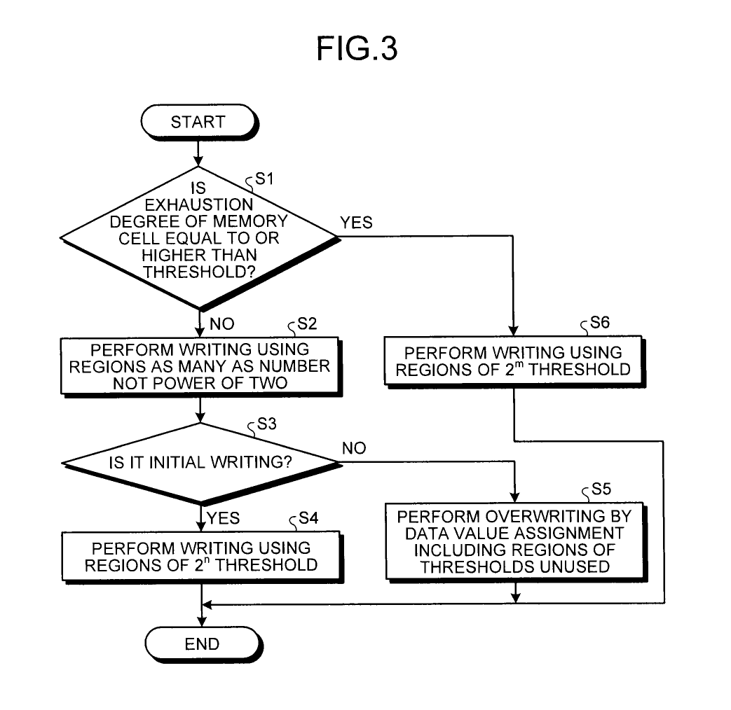

FIG. 3 is a flowchart illustrating an example of a writing sequence of the embodiment. In a case where a writing request is transmitted from the host 4, the control unit 23 determines a memory region on the nonvolatile memory 3 at a writing destination of the unit data which is generated based on the user data received from the host 4. The control unit 23 stores the exhaustion degree of the memory cell as exhaustion degree information in a unit of memory cell group or a unit of block. The control unit 23 obtains the exhaustion degree of the memory cell in the memory region at the writing destination of the unit data based on the exhaustion degree information, and determines whether the exhaustion degree is equal to or higher than the threshold (the first value) (step S1). A method of obtaining the exhaustion degree will be described below. In a case where the exhaustion degree is less than the threshold (No in step S1), the control unit 23 determines that a writing is performed using regions of a non-power-of-two number of threshold voltages (step S2). Hereinafter, the writing using regions of a non-power-of-two number of threshold voltages is referred to as a “fractional-bit writing” (a first procedure).

Further, the control unit 23 determines whether the writing is performed by the initial writing or by the overwriting in the fractional-bit writing (step S3). In addition, the control unit 23 stores a writing mode for each memory cell group as writing mode information, and determines whether the writing is performed by the initial writing based on the writing mode information.

The control unit 23 instructs the assignment control unit 28 to operate in the determined writing mode. In the embodiment, the following three types of writing modes are defined.
An initial writing in the fractional-bit writing (a first writing mode)
An overwriting in the fractional-bit writing (a second writing mode)
A writing of a normal MLC using distribution of a power-of-two number of thresholds (a third writing mode)

In addition, herein, similarly to MLC4-4, an example in which the overwriting is performed one time will be described, but the embodiment is applicable even to a case where the overwriting is performed two or more times similarly to MLC4-4-4. In a case where the overwriting is performed two or more times, it is also determined how many times the overwriting is performed. The details of a method of determining the writing mode will be described below. The control unit 23 instructs the assignment control unit 28 to perform the writing by the initial writing or by the overwriting for each unit data.

In a case where the control unit 23 determines that the initial writing is performed (Yes in step S3), the assignment control unit 28 determines that the writing is performed in the first writing mode based on the writing mode instructed from the control unit 23. Then, the assignment control unit 28 performs the writing onto the nonvolatile memory 3 using regions of 2ⁿ threshold voltages (n is an integer of 2ⁿ<Z) (step S4). In the example of FIG. 2, n is set to “2” (n=2), and the writing of 2 bits is performed by the initial writing of MLC4-4 illustrated in the upper part in step S2. Specifically, the assignment control unit 28 instructs the memory I/F 22 to perform the writing using regions of the 2ⁿ threshold voltages of a non-power-of-two number of regions. The memory I/F 22 designates an address indicating a memory group at the writing destination of the data and information indicating the initial writing as the writing mode, and instructs the nonvolatile memory 3 to write the data. The nonvolatile memory 3 performs the writing according to the instruction from the memory I/F 22.

On the other hand, in a case where the control unit 23 determines that the writing is performed by the overwriting (No in step S3), the assignment control unit 28 determines that the writing is performed in the second writing mode based on the writing mode instructed from the control unit 23. Then, the assignment control unit 28 performs the writing onto the nonvolatile memory 3 through the data value assignment in which the regions having not been used in the data value assignment of the initial writing is used (step S4). In addition, in a case where the overwriting is performed two or more times, the assignment control unit 28 performs the writing onto the nonvolatile memory 3 using the data value assignment method according to the number of times the overwriting is performed, based on the information which indicates how many times the overwriting is performed and notified from the control unit 23.

Further, in step S1, in a case where the exhaustion degree is equal to or higher than the threshold (Yes in step S1), the control unit 23 instructs the assignment control unit 28 to perform the writing of the normal MLC in which the regions of the 2^{m} threshold voltages are used. Hereinafter, the writing of the normal MLC in which the regions of the 2^{m} threshold voltages are used is referred to as an “integer-bit writing”(a second procedure). In other words, the control unit 23 instructs the assignment control unit 28 to operate in the third writing mode (the integer-bit writing) as the writing mode. Then, the assignment control unit 28 performs the writing using the regions of 2^{m} threshold voltages based on the instructed writing mode (step S6). In the example of FIG. 2, m is set to “2” (m=2), and the writing of 2 bits is performed by MLC4 illustrated in the lower part in step S5.

The above-mentioned writing sequence is performed for each piece of the user data (that is, page) to be written. However, in a case where the multi-level cell is used, since one memory cell group corresponds to the plurality of pages, the writing mode is determined for each memory cell group not the unit of page. Herein, it is assumed that the plurality of pages corresponding to the same memory cell group are continuously written, and the writing mode is not different between the pages corresponding to the same memory cell group. In addition, a minimum unit of determining the writing mode is the memory cell group, but the writing mode may be determined not in a unit of memory cell group but in a unit of block which is a unit of erasing. In this case, an encoding operation may be performed in a unit of data which is included in the block.

Next, the exhaustion degree of the memory cell will be described. As the exhaustion degree of the memory cell, for example, the following items may be used.
(a) Number of times of writing
(b) Number of times of erasing
(c) Number of errors on reading, or amount equivalent to errors

The above items (a) and (b) are generally managed in a unit of block by the control unit 23. Therefore, the control unit 23 uses the managed item (a) or (b) as the exhaustion degree information to obtain the exhaustion degree of the memory cell in a unit of block. Further, the exhaustion degree of the memory cell may be obtained using both the items (a) and (b). For example, in step S1 described above, in a case where the number of times of writing is equal to or larger than a first threshold and the number of times of erasing is equal to or larger than a second threshold, the determination result becomes “Yes”, and the procedure may proceed to step S6. Alternatively, in step S1 described above, in a case where the number of times of writing is equal to or larger than the first threshold or the number of times of erasing is equal to or larger than the second threshold, the determination result becomes “Yes”, and the procedure may proceed to step S6.

In a case where the above item (c) is used as the exhaustion degree of the memory cell, it is assumed that the user data has been encoded at the time of writing. For example, as described above, the encoding unit 25 encodes the first unit data to generate the first code word, and encodes the second unit data to generate the second code word. In this way, the encoding unit 25 generates the code word for each piece of the unit data. Then, one code word is written in the same page or the same memory cell group of the nonvolatile memory 3. The decoding unit 26 decodes the code word read out of the nonvolatile memory 3. In general, the number of error bits in the code word is calculated in a decoding procedure. Therefore, the number of error bits can be used as the exhaustion degree of the memory cell. The control unit 23 acquires the number of error bits from the decoding unit 26, and stores the number of error bits per one code word for each memory cell group as the exhaustion degree information.

Further, in a case where the encoding is performed in multi-stages, the subject stage where the decoding is performed becomes information corresponding to the above item (c). Therefore, the information indicating the subject stage where the decoding is performed can be used as the above item (c). In a case where the overwriting is performed in a unit of block, a product code is prepared in a unit of block, and information indicating that the product code is decoded can be used as the information of the item (c). Further, similarly to the LDPC code, in a case where a hard decision decoding and a soft decision decoding can be separately used, information indicating that the soft decision decoding is performed can also be used as the information of item (c). In the following, an example of performing a two-stage encoding will be described.

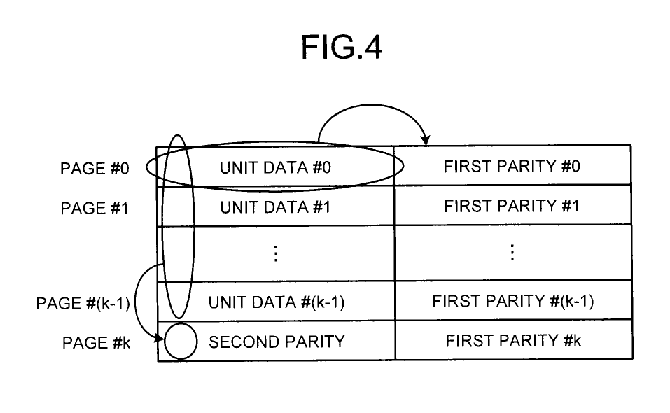

FIG. 4 is a diagram illustrating an example of the two-stage encoding. First, the encoding unit 25 encodes the first unit data (unit data #0) as an encoding of the first stage to generate a first parity #0, and encodes the second unit data (unit data #1) to generate a first parity #1. Similarly, the encoding unit 25 encodes third unit data (unit data #2) to k-th unit data (unit data #(k-1)) to generate a first parity #3 to a first parity #(k-1). One code word (the first parity corresponding to the unit data) is stored in the same page.

Furthermore, as the encoding of the second stage, the encoding unit 25 generates a parity symbol contained in a second parity using some symbols of the unit data #0, the unit data #1, . . . , and the unit data #(k-1). The encoding of the second stage is performed to protect all the data of the unit data #0, the unit data #1, . . . , and the unit data #(k-1) by any of the parity symbols. In FIG. 4, a parity symbol group generated by the encoding of the second stage is denoted as the second parity. The encoding unit 25 generates a first parity #k on which the encoding of the first stage is performed for the second parity. The second parity and the first parity #k are stored in the same page.

In a case where the two-stage encoding as illustrated in FIG. 4 is performed, the decoding unit 26 first performs decoding of the first stage, that is, the decoding using the first parity when the reading is performed from the nonvolatile memory 3. Then, in a case where the error correction is not possible by the decoding of the first stage, the decoding unit 26 performs the decoding of the second stage, that is, the decoding using the second parity. When the error correction is not possible by the decoding of the first stage, it indicates that there are some errors in number which are not corrected in the decoding of the first stage. Therefore, the control unit 23 manages whether the decoding of the second stage is performed for each memory cell group as the exhaustion degree information. In step S1 described above, the control unit 23 determines that the exhaustion degree of the memory cell group subjected to the decoding of the second stage is equal to or higher than the threshold based on the exhaustion degree information.

In addition, the encoding illustrated in FIG. 4 is given as merely exemplary, and the multi-stage encoding is not limited to the example of FIG. 4. Generally, in a case where the encoding is performed in multi-stages, the number of stages of the decoding is increased according to the number of errors; for example, when the decoding of the first stage is failed, the decoding of the second stage is performed, and when the decoding of the second stage is failed, the decoding of the third stage is performed. Therefore, even in a case where the encoding in multi-stages other than the example of FIG. 4 is performed, the information indicating the subject stage where the decoding is performed can be used as the exhaustion degree.

In addition, in the sequence illustrated in FIG. 3, when the control unit 23 stores the exhaustion degree information and the writing to the nonvolatile memory 3 is performed, the writing mode is determined based on the exhaustion degree information. However, the control unit 23 may store a determination result on whether the exhaustion degree is equal to or higher than the threshold instead of storing the exhaustion degree information. Then, in step S1, the determination result is referred to instead of determination on whether the exhaustion degree is equal to or higher than the threshold.

Next, the reading from the nonvolatile memory 3 will be described. At the time of performing the reading, the control unit 23 ascertains the writing mode based on the writing mode information which is stored therein, and the writing mode of the memory cell group which is a target to be read is notified to the assignment control unit 28. The assignment control unit 28 reads data out of the nonvolatile memory 3 through the memory I/F 22 based on the data value assignment method corresponding to the designated writing mode. Further, the writing mode information may be stored not in the control unit 28, but in the nonvolatile memory 3. For example, (A) a method in which a page only having one type of writing mode is used, or (B) a method in which the writing mode is recorded in the memory cell group as disclosed in U.S. Provisional Application No. 61/985,323 may be used.

Further, in the above example, the method of separately using MLC4-4 and MLC4 according to the exhaustion degree has been described, but the separate usage may be determined by whether data is expected to be stored for a long time. In a case where the data is expected to be stored for a long time, the control unit 23 writes the data by MLC4 without making determination according to the exhaustion degree. It is desirable that the determination on whether the data is expected to be stored for a long time is explicitly designated from the host 4 by the control unit 23, and the determination may be independently made by the memory controller 2. As an example of the explicit designation from the host 4, there is an example in which an attribution is given to the data received by the host 4. The control unit 23 determines whether the data is expected to be stored for a long time based on the attribution.

As described above, in the embodiment, the writing using a non-power-of-two number of regions and the writing of the normal MLC are separately used according to the exhaustion degree. Therefore, in a case where the exhaustion degree becomes high, the data error can be reduced. Further, during a period when the exhaustion degree is less than the threshold, the storage capacity for writing until the first erasing can be increased compared to a case where MLC8 is used.

### Second Embodiment

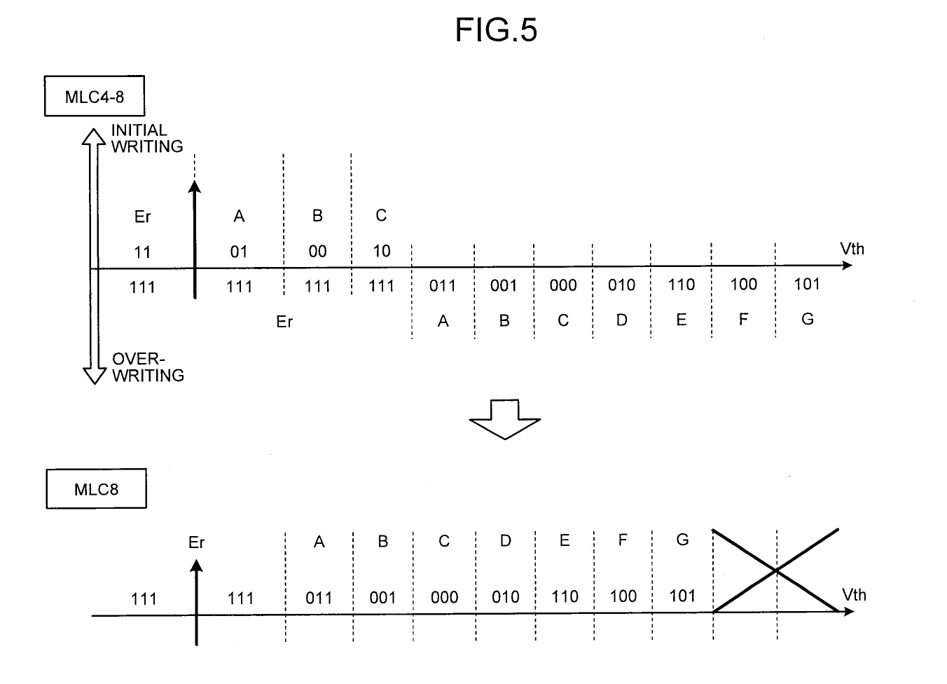

Next, the writing method of a second embodiment will be described. The configuration of the semiconductor storage device 1 of the embodiment is the same as that of the first embodiment. FIG. 5 is a diagram illustrating an example of the writing method of the embodiment. In the embodiment, similarly to the first embodiment, during a period when the exhaustion degree is low, the writing in which a non-power-of-two number of regions are used is performed. In a case where the exhaustion degree is equal to or higher than the threshold, the writing of the normal MLC (the writing using 2^{m} regions) is performed.

In the example of FIG. 5, during a period when the exhaustion degree is low, the writing is performed by MLC4-8 as illustrated in the upper part of FIG. 5, and in a case where the exhaustion degree is equal to or higher than the threshold, the writing is performed by MLC8 as illustrated in the lower part of FIG. 5. In the writing of MLC4-8, the regions of 11 threshold voltages are used. Then, in the initial writing, the writing of 2 bits is performed by the data value assignment using four regions in an ascending order of the threshold voltage from the lowest one in the 11 regions. In the overwriting, four regions used in the data value assignment of the initial writing is set to one combination region, and the writing of 3 bits is performed by the data value assignment using total eight regions (regions Er, A, B, C, D, E, F, and G) of the combination region and seven regions unused in the data value assignment of the initial writing.

In MLC8, the regions of the highest threshold voltage and the second highest threshold voltage are not used in the regions of 11 threshold voltages used in MLC4-8. Further, as region Er, a region obtained by combining the regions of the lowest threshold voltage and the second lowest threshold voltage is used in the regions of 11 threshold voltages used in MLC4-8. In FIG. 5, similarly to the example of FIG. 2 of the first embodiment, it is assumed that region Er is unstable. As described even in the first embodiment, eight regions used in MLC8 are not limited to the example of FIG. 5.

The separate usage between MLC4-8 and MLC8 according to the exhaustion degree of the embodiment is the same as that between MLC4-4 and MLC4 of the first embodiment. In the writing method disclosed in U.S. Provisional Application No. 61/985,323, when the overwriting is performed, data before the overwriting (data written by the initial writing) is not allowed to be read. Therefore, in a case where data stored in the memory cells subjected to the initial writing is not needed any more, the overwriting onto the respective memory cells is performed. In the embodiment, the number of bits to be written by the overwriting is larger than the number of bits to be written by the initial writing. Therefore, even in a case where the data stored in the memory cells subjected to the initial writing is not unnecessary, the overwriting can be performed.

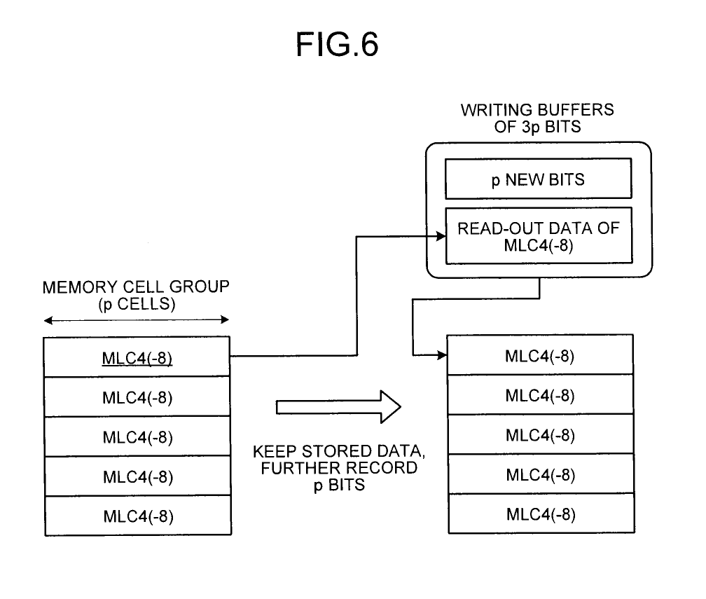

FIG. 6 is a diagram illustrating an example of writing data at the time of the overwriting of the embodiment. MLC4(-8) on the left side of FIG. 6 illustrates the memory cell group in a state where the initial writing of MLC4-8 illustrated in FIG. 5 is performed. The number of memory cells included in the memory cell group is denoted by “p”. One rectangular illustrates one memory cell group.

In order to write p bits of new information in the memory cell group of MLC4(-8) while the data written by the initial writing is left, the control unit 23 first makes control to read data from the memory cell group of MLC4(-8). Then, the read-out data is stored in the data buffer 27 or a buffer (not illustrated in FIG. 1). Further, the p bits of information newly written (“p new bits” of FIG. 6) are also stored in the data buffer 27 or the buffer (not illustrated in FIG. 1). In order to store the “p new bits” and the read-out data (“read-out data of MLC4(-8)” of FIG. 6), as illustrated in the right upper of FIG. 6, there is required buffers as many as 3p bits per memory cell group.

Next, the control unit 23 instructs the assignment control unit 28 to write a total 3p bits of “p new bits” and “read-out data of MLC4(-8)” stored in the data buffer 27 or the buffer (not illustrated in FIG. 1) by the overwriting (the second writing mode). The assignment control unit 28 writes 3p bits by the overwriting onto the memory cell group of MLC4(-8) where the “read-out data of MLC4(-8)” is stored by the data value assignment corresponding to the overwriting of MLC4-8. In addition, in a case where the user data is encoded and written in the nonvolatile memory 3, the “read-out data of MLC4(-8)” is the code word, and the “p new bits” are also the code word. The “read-out data MLC4(-8)” may be decoded once to eliminate an error. In a case where there is no need to eliminate an error due to a time interval, the decoding may be not performed.

MLC(4-)8 of FIG. 6 illustrates the memory cell group in a state where the overwriting of MLC4-8 is performed. Through the above process, while storing the data written by the initial writing, new data can be additionally written. Other operations of the embodiment besides the above operation are the same as those of the first embodiment.

In the examples of FIGS. 5 and 6, MLC4-8 and MLC8 are separately used according to the exhaustion degree, but the writing method of the embodiment is not limited to these examples. Similarly, as long as the number of bits to be written by the overwriting is larger than the number of bits to be written by the initial writing, new data can be additionally written in the writing using a non-power-of-two number of regions while the data to be written by the initial writing is stored.

Further, in a case where the overwriting is performed plural times, it is possible to additionally write new information while the data already written is stored as long as the number of bits to be written is increased as the overwriting is repeated such that the number of bits to be written by a first overwriting is larger than that of the initial writing, the number of bits to be written by a second overwriting is larger than that of the first overwriting and so on. For example, in the case of MLC2-4-8, 1 bit per memory cell is written in the initial writing, 1 bit is written in the first overwriting in addition to 1 bit written in the initial writing, and 1 bit is further written in the second overwriting in addition to 2 bits written in the first overwriting.

In addition, as described above, only in a case where the data written in the initial writing is necessarily kept continuously stored, the data is written at the time of the overwriting also including the data written in the initial writing. When the memory cell group is not needed to keep the data written in the initial writing, only new data may be written at the time of the overwriting.

As described above, in the embodiment, the writing using a non-power-of-two number of regions and the normal MLC writing are separately used according to the exhaustion degree. In the writing using a non-power-of-two number of regions, the number of bits to be written by the overwriting is larger than the number of bits to be written by the initial writing. Then, at the time of the overwriting, the data of the initial writing is read, and the read data and the new data are written. Therefore, the same effect as that of the first embodiment is achieved, and further it is possible to overwrite the new data while storing the data already written in the writing using a non-power-of-two number of regions. With this configuration, it is possible to realize the guaranteed storage capacity without paying attention to data occupancy of the host in the storage device. More specifically, when a guaranteed temporary storage capacity is set to 2^{m}, and t_{q} in MLCt₁-t₂- . . . -t_{q} is set to be equal to 2^{m} and thus t₁, t₂, . . . , and t_{q-1} are made equal to or less than 2^{m}, the guaranteed storage capacity can be realized without paying attention to the data occupancy of the host.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device comprising:
a nonvolatile memory having multiple memory cells that can store data by having a set threshold voltage thereof included in one of threshold regions divided according to multiple read-out voltages; and
a memory controller configured to perform reading and writing data from and into the nonvolatile memory,
wherein the memory cell is configured to set Z threshold regions, Z being a positive number not a power of two, and to set 2^{m} threshold regions when m is an integer of 1 or more, 2^{m} being smaller than Z,
wherein when an exhaustion degree of a first memory cell of the nonvolatile memory is less than a first value, the memory controller performs a first procedure, the first procedure being a writing in which the number of threshold regions of the first memory cell is set to Z with respect to the first memory cell, and
wherein when the exhaustion degree of the first memory cell is equal to or higher than the first value, the memory controller performs a second procedure, the second procedure being a writing in which the number of threshold regions of the first memory cell is set to 2^{m} with respect to the first memory cell.

2. The storage device according to claim 1,
wherein in the first procedure,
a first writing is performed on the first memory cell based on a first data value assignment in which 2ⁿ data values are associated with 2ⁿ threshold regions, where n and h are integers and 2ⁿ+(2^{h}−1) is equal to or smaller than Z, and
a second writing is performed on the first memory cell subjected to the first writing based on a second data value assignment in which 2^{h} data values are associated with 2^{h} regions including the threshold region which is not used in the first data value assignment without erasing the data written in the first writing,
wherein in the second data value assignment,
a power-of-two number of threshold regions used in the first data value assignment are set to one first combination region, and
the first combination region and a threshold region unused in the first data value assignment are associated with 2^{h} data values, and
wherein in the second procedure,
a third writing is performed based on a third data value assignment in which 2^{m} threshold regions are associated with 2^{m} data values.

3. The storage device according to claim 2,
wherein h=m.

4. The storage device according to claim 2,
wherein n<h.

5. The storage device according to claim 4,
wherein in the second writing,
first data written by the first writing is read out of the first memory cell, and
the read-out first data and second data to be newly written in the nonvolatile memory are written in the first memory cell based on the second data value assignment.

6. The storage device according to claim 1,
wherein the exhaustion degree is the number of times of erasing performed on the memory cell.

7. The storage device according to claim 1,
wherein the exhaustion degree is the number of times of writing performed on the memory cell.

8. The storage device according to claim 1,
wherein the memory controller includes
an encoding unit configured to encode the data to generate a code word, and
a decoding unit configured to decode the code word read out of the nonvolatile memory, and calculate the number of error bits in the code word or information from which the number of error bits is estimated,
wherein the memory controller writes the code word to the nonvolatile memory, and
wherein the memory controller calculates the exhaustion degree based on the number of error bits.

9. The storage device according to claim 1,
wherein the memory controller includes
an encoding unit configured to encode the data in multi-stages to generate a code word, and
a decoding unit configured to decode the code word read out of the nonvolatile memory in multi-stages,
wherein the memory controller writes the code word to the nonvolatile memory, and
wherein the memory controller calculates the exhaustion degree based on the number of stages where the decoding unit performs the decoding.

10. A memory controller which performs reading and writing data from and into a nonvolatile memory configured to include multiple memory cells that can store data by having a set threshold voltage thereof included in one of threshold regions divided according to multiple read-out voltages,
the memory controller comprising:
a control unit configured to,
when an exhaustion degree of a first memory cell of the nonvolatile memory is less than a first value,
perform a first procedure, the first procedure being a writing in which the number of threshold regions of the first memory cell is set to Z with respect to the first memory cell, Z being a positive number not a power of two, and
when the exhaustion degree of the first memory cell is equal to or higher than the first value,
perform a second procedure, the second procedure being a writing in which the number of threshold regions of the first memory cell is set to 2^{m} with respect to the first memory cell, m being an integer of 1 or more;
wherein the memory cell is configured to set Z threshold regions, and to set 2^{m} threshold regions, 2^{m} being smaller than Z.

11. The memory controller according to claim 10,
wherein in the first procedure,
a first writing is performed on the first memory cell based on a first data value assignment in which 2ⁿ data values are associated with 2ⁿ threshold regions, where n and h are integers and 2ⁿ+(2^{h}−1) is equal to or smaller than Z, and
a second writing is performed on the first memory cell subjected to the first writing based on a second data value assignment in which 2^{h} data values are associated with 2^{h} regions including the threshold region which is not used in the first data value assignment without erasing the data written in the first writing,
wherein in the second data value assignment,
a power-of-two number of threshold regions used in the first data value assignment are set to one first combination region, and
the first combination region and a threshold region unused in the first data value assignment are associated with 2^{h} data values, and
wherein in the second procedure,
a third writing is performed based on a third data value assignment in which 2^{m} threshold regions are associated with 2^{m} data values.

12. The memory controller according to claim 11,
wherein h=m.

13. The memory controller according to claim 11,
wherein n<h.

14. The memory controller according to claim 13,
wherein in the second writing,
first data written by the first writing is read out of the first memory cell, and
the read-out first data and second data to be newly written in the nonvolatile memory are written in the first memory cell based on the second data value assignment.

15. The memory controller according to claim 10,
wherein the exhaustion degree is the number of times of erasing performed on the memory cell.

16. The memory controller according to claim 10,
wherein the exhaustion degree is the number of times of writing performed on the memory cell.

17. The memory controller according to claim 10, further comprising:
an encoding unit configured to encode the data to generate a code word; and
a decoding unit configured to decode the code word read out of the nonvolatile memory, and calculate the number of error bits in the code word,
wherein the memory controller writes the code word to the nonvolatile memory, and
wherein the memory controller calculates the exhaustion degree based on the number of error bits.

18. The memory controller according to claim 10, further comprising:
an encoding unit configured to encode the data in multi-stages to generate a code word; and
a decoding unit configured to decode the code word read out of the nonvolatile memory in multi-stages,
wherein the memory controller writes the code word to the nonvolatile memory, and
wherein the memory controller calculates the exhaustion degree based on the number of stages where the decoding unit performs the decoding.

19. A memory control method of nonvolatile memory, the nonvolatile memory including multiple memory cells that can store data by having a set threshold voltage thereof included in one of threshold regions divided according to multiple read-out voltages, the memory control method comprising:
when an exhaustion degree of a first memory cell of the nonvolatile memory is less than a first value,
performing first procedure, the first procedure being a writing in which the number of threshold regions of the first memory cell is set to Z with respect to the first memory cell, Z being a positive number not a power of two; and
when the exhaustion degree of the first memory cell is equal to or higher than the first value,
performing a second procedure, the second procedure being a writing in which the number of threshold regions of the first memory cell is set to 2^{m} with respect to the first memory cell, m being an integer of 1 or more,
wherein the memory cell is configured to set Z threshold regions, and to set 2^{m} threshold regions, 2^{m} being smaller than Z.

20. The memory control method according to claim 19,
wherein in the first procedure,
a first writing is performed on the first memory cell based on a first data value assignment in which 2ⁿ data values are associated with 2ⁿ threshold regions, where n and h are integers and 2ⁿ+(2^{h}−1) is equal to or smaller than Z, and
a second writing is performed on the first memory cell subjected to the first writing based on a second data value assignment in which 2^{h} data values are associated with 2^{h} regions including the threshold region which is not used in the first data value assignment without erasing the data written in the first writing,
wherein in the second data value assignment,
a power-of-two number of threshold regions used in the first data value assignment are set to one first combination region, and
the first combination region and a threshold region unused in the first data value assignment are associated with 2^{h} data values, and
wherein in second procedure,
a third writing is performed based on a third data value assignment in which 2^{m} threshold regions are associated with 2^{m} data values.
